(19) United States
(12) Patent Application Publication
(10) Pub. No.: US 2016/0179230 A1
(43) Pub. Date: Jun. 23, 2016

(54) ELECTROACTIVE LAYER COUPLED TO A FLEXIBLE DISPLAY

(71) Applicant: Intel Corporation, Santa Clara, CA (US)

(72) Inventors: Tomer Rider, Naahryia (IL); Dor Levy, Jerusalem (IL)

(73) Assignee: INTEL CORPORATION, Santa Clara, CA (US)

(21) Appl. No.: 14/581,438

(22) Filed: Dec. 23, 2014

(51) Int. Cl. G06F 3/041; H05K 5/00; G06F 1/16; H05K 1/02

(52) U.S. Cl. CPC G06F 3/041; H05K 1/028; H05K 5/0017; G06F 1/1652; G06F 2203/04102

(57) ABSTRACT

Techniques related to flexible displays are described herein. The techniques include a flexible display and an electroactive layer coupled to the flexible display. Shape changes in the electroactive layer are configured to generate shape changes in the flexible display.

### TECHNICAL FIELD

This disclosure relates generally to flexible displays. More specifically, the techniques described herein include coupling an electroactive material to a flexible display.

### BACKGROUND ART

In computer systems, a display device may be used to display various image content. In some cases, curved display devices may be used. However, not all consumers prefer curved displays. Further, in some cases, a given curve of a display may not be useful under certain conditions, contexts, and environments.

### BRIEF DESCRIPTION OF THE DRAWINGS

FIG. 1 is a block diagram illustrating a computing device configured to generate shape changes at a flexible display;

FIG. 2 is block diagram illustrating a flexible display and an electroactive layer;

FIG. 3 is a state diagram illustrating shape changes of a flexible display coupled to an electroactive layer;

FIG. 4 is a diagram illustrating a side view of a flexible display and the electroactive layer having multiple sections;

FIG. 5 is a block diagram illustrating a method for forming a shape changing flexible display; and

FIG. 6 is a block diagram depicting an example of a computer-readable medium configured to implement shape changes at a flexible display.

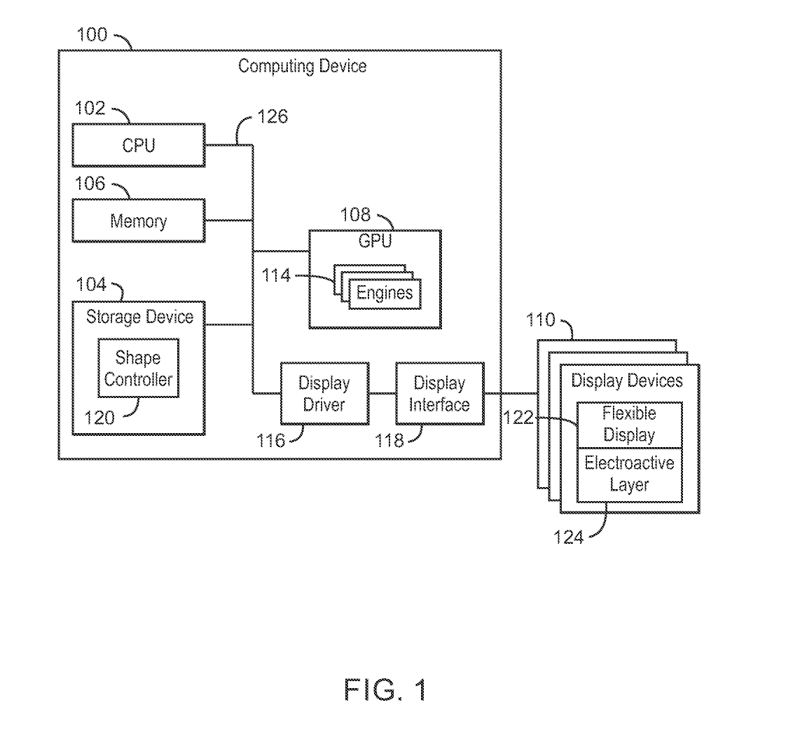

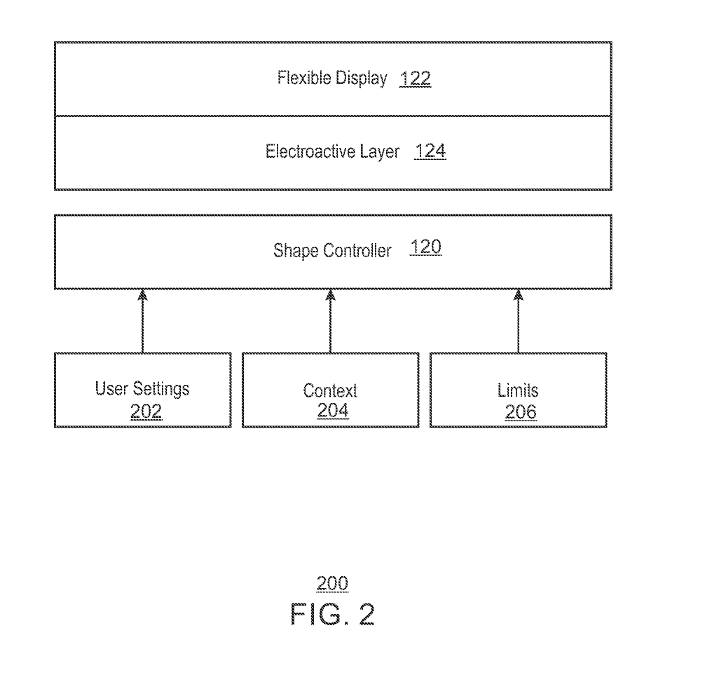

The same numbers are used throughout the disclosure and the figures to reference like components and features. Numbers in the 100 series refer to features originally found in FIG. 1; numbers in the 200 series refer to features originally found in FIG. 2; and so on.

### DETAILED DESCRIPTION

The subject matter disclosed herein relates to techniques for flexible displays coupled to an electroactive layer. As discussed above, curved display devices are becoming popular. However, not all consumers may prefer a curved display. Further, in some conditions, a display having a fixed curve that is not changeable may not be desirable. The techniques described herein include a flexible display that is dynamically changeable in shape as electric force is applied to an electroactive layer coupled to the flexible display.

An electroactive layer may be a material responding in size or shape to an electric field. The electroactive layer may be composed of electroactive polymers (EAPs) for example. EAPs are polymers that exhibit a change in size or shape when stimulated by an electric field.

A flexible display may include any display that is flexible and may respond to changes in shape of the electroactive layer. For example, as current is provided to the electroactive layer, the electroactive layer may change in shape. Changes in the shape of the electroactive layer may be reflected by a change in shape at the flexible display. Therefore, a curve of a flexible display may be increased or reduced, based on user preferences, or other types of conditions discussed in more detail below.

Although aspects presented herein generally discuss one layer of electroactive material coupled to a flexible display, multiple layers may be implemented. In some cases, multiple layers may increase strength of by the combination of the flexible display and multiple electroactive layers. Further, in some cases, a shape formation effect may be increased by the use of multiple layers in various configurations, and are contemplated herein.

FIG. 1 is a block diagram illustrating a computing device configured to generate shape changes at a flexible display. The computing device 100 may be, for example, a laptop computer, desktop computer, ultrabook, tablet computer, mobile device, or server, among others. The computing device 100 may include a processing device 102 that is configured to execute stored instructions, as well as a storage device 104 including a non-transitory computer-readable medium, and a memory device 106.

The computing device 100 may also include a graphics processing unit (GPU) 108. In embodiments, the GPU 108 is on board ore is embedded in the processing device 102. The GPU 108 may include a cache, and can be configured to perform any number of graphics operations within the computing device 100. For example, the GPU 108 may be configured to render or manipulate graphics images, graphics frames, videos, or the like, to be displayed to a user of the computing device 100 at one or more display devices 110. Displaying image data may be carried out by one or more of engines 114 of the GPU 108, a display driver 116, a display interface 118, and the like. The display devices 110 may be implemented as external display devices, as internal display device, or any combination thereof.

In some cases, the engines 114 may be configured to perform shape changes as directed by instructions of a shape controller 120. In some cases, the shape controller 120 may be implemented as logic, at least partially comprising hardware logic. In other cases, the shape controller 120 may be implemented as a portion of software instructions of the display driver 116. Software instructions may be configured to be carried out by the engines 114 of the GPU 108, by the processing device 102, or any other suitable controller. In yet other cases, the shape controller 120 may be implemented as electronic logic, at least partially comprising hardware logic, to be carried out by electronic circuitry, circuitry to be carried out by an integrated circuit, and the like. The shape controller 120 may be configured to operate independently, in parallel, distributed, or as a part of a broader process. In yet other cases, the shape controller 120 may be implemented as a combination of software, firmware, hardware logic, and the like.

As discussed above, one or more of the display devices 110 may include a flexible display 122. The shape controller 120 may be configured to adjust a shape of the flexible display 122 by adjusting changes in electric force applied to an electroactive layer 124 coupled to the flexible display 122.

In some cases, the shape changes performed by the shape controller 120 are based on one or more conditions. For example, the shape controller 120 may adjust a shape of the flexible display 122 based on one or more user settings. As another example, the shape of the flexible display 122 may be adjusted based on content of images to be displayed at the flexible display 122. In this scenario, some image content may be configured to be displayed at the flexible display 122 having a specific curve, or shape. Therefore, the shape controller 120 may be configured to adjust the shape of the flexible display by changing characteristics of the electric force, such as strength of an electromagnetic field, current level, voltage level, level of ambient light and the like.

In some cases, the shape controller 120 may be configured to change the shape of the flexible display 122 based on the presence of a given user and preferences of the user stored in a user profile. In some cases, contextual data indicating an environment within which the flexible display is disposed may be a condition from which the shape controller 120 either modifies or maintains a given shape. Examples of contextual data may include time of day, location, temperature, and the like.

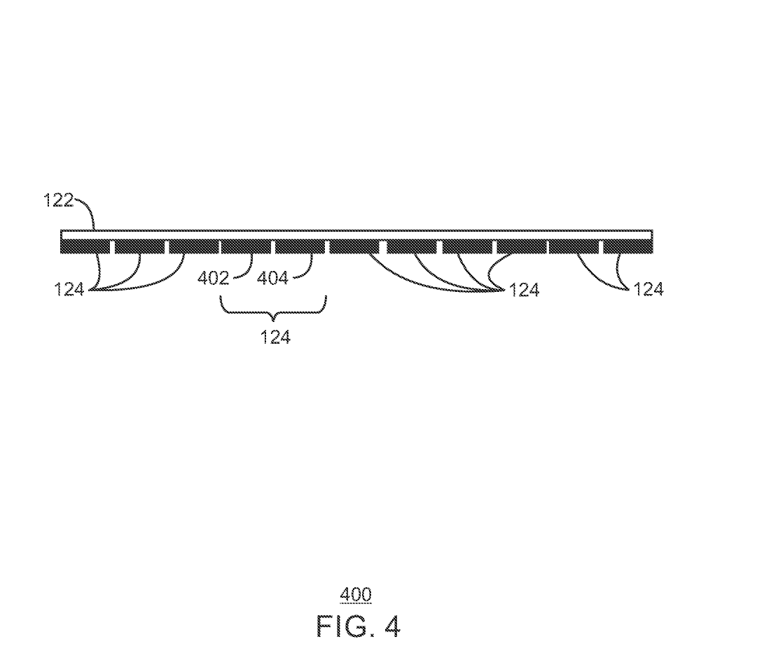

As discussed in more detail below, the shape of the flexible display may be dependent upon characteristics of the electroactive material. For example, the electroactive material may be composed of discrete sections wherein different current levels may be provided to different sections to generate more than one curve at the flexible display 122. Other characteristics, such as different resistances, flexors, and the like may be implemented, as discussed in more detail below in regard to FIG. 4.

The memory device 106 can include random access memory (RAM), read only memory (ROM), flash memory, or any other suitable memory systems. For example, the memory device 106 may include dynamic random access memory (DRAM). The memory device 106 can include random access memory (RAM) (e.g., static random access memory (SRAM), dynamic random access memory (DRAM), zero capacitor RAM, Silicon-Oxide-Nitride-Oxide-Silicon SONOS, embedded DRAM, extended data out RAM, double data rate (DDR) RAM, resistive random access memory (RRAM), parameter random access memory (PRAM), etc.), read only memory (ROM) (e.g., Mask ROM, programmable read only memory (PROM), erasable programmable read only memory (EPROM), electrically erasable programmable read only memory (EEPROM), etc.), flash memory, or any other suitable memory systems.

The processing device 102 may be a main processor that is adapted to execute the stored instructions. The processing device 102 may be a single core processor, a multi-core processor, a computing cluster, or any number of other configurations. The processing device 102 may be implemented as Complex Instruction Set Computer (CISC) or Reduced Instruction Set Computer (RISC) processors, x86 Instruction set compatible processors, multi-core, or any other microprocessor or central processing unit (CPU). The processing device 102 may be connected through a system bus 126 (e.g., Peripheral Component Interconnect (PCI), Industry Standard Architecture (ISA), PCI-Express, HyperTransport®, NuBus, etc.) to components including the memory 106 and the storage device 104. The processing device 102 may also be linked through the bus 126 to the display driver 116 and the display interface 118 configured to connect the computing device 100 to display devices 110 via a digital display interface. The display devices 110 may include a computer monitor, television, projector, among others, that are connected to the computing device 100.

In some cases, the computing device 100 may be a mobile computing device. In some cases, the display devices 110 may be mobile display devices to a mobile computing device.

The block diagram of FIG. 1 is not intended to indicate that the computing device 100 is to include all of the components shown in FIG. 1. Further, the computing device 100 may include any number of additional components not shown in FIG. 1, depending on the details of the specific implementation.

FIG. 2 is block diagram illustrating a flexible display and an electroactive layer. The block diagram 200 illustrates a side view of a flexible display, such as the flexible display 122 of FIG. 1, coupled to an electroactive layer, such as the electroactive layer 124 of FIG. 1. The flexible display 122 and the electroactive layer 124 may be coupled via any feasible means. For example, the flexible display 122 and the electroactive layer 124 may be coupled using an adhesive, by way of a frame of a display device, by mechanical connectors at strategic locations, and the like.

As discussed above, a controller, such as the shape controller 120 of FIG. 1, may alter the shape of the flexible display by applying an electric force to the electroactive layer 124. A resulting shape may be configurable based on various inputs. For example, the shape controller 120 may shape the flexible display 122 based on user's personal settings 202. In other cases, the shape controller 120 may shape the flexible display 122 based on context 204 such as a time of day, a location, an ambient light level, and the like. In some cases, the shape controller 120 may shape the flexible display based on limits 206 associated with characteristics of the flexible display 122, the electroactive layer 124, or any combination thereof. For example, the limits 206 may include a slope of a curve maximum to prevent breakage of the flexible display 122.

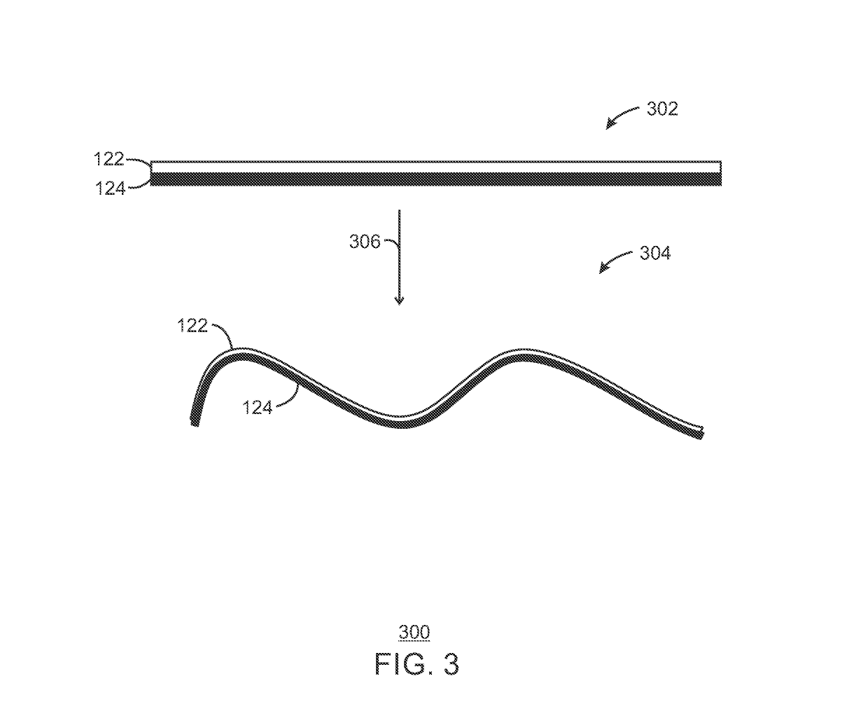

FIG. 3 is a state diagram illustrating shape changes of a flexible display coupled to an electroactive layer. FIG. 3 illustrates a side view 300 of a flexible display and electroactive layer, such as the flexible display 122 and the electroactive layer 124 of FIG. 1 discussed above.

In some cases, when no electric force is applied to the electroactive material 122, the flexible display may lay flat as generally indicated at 302. As electric force, such as electric force associated with a current, is applied to the electroactive material 124, a shape 304 may form as generally indicated by the arrow 306. The shape 304 may be one curve, or may include multiple curves depending on characteristics of the electroactive layer 124, as discussed in more detail below in regard to FIG. 4.

FIG. 4 is a diagram illustrating a side view of a flexible display and the electroactive layer having multiple sections. As discussed above, the electroactive layer 124 may include characteristics enabling multiple curves to be generated at the flexible display 122. In FIG. 4, a side view 400 illustrates that the electroactive layer 124 may include multiple sections. The multiple sections may be electrically isolated or at least electrically independent enough such that different sections may be configured to receive different electric forces. For example, a first section 402 may be configured to receive a different voltage level, or voltage having a different current, than a second section 404 of the electroactive material 124.

Although FIG. 4 illustrates the electroactive layer 124 being separated into discrete sections, the characteristics enabling the flexible display to be formed into multiple turns need not be discrete sections. For example, in some cases, various areas of the electroactive layer 124 may include resistors, flexors, varying types of electroactive material, or any other electrically active components or designs enabling varying types of forces to shape varying portions of the electroactive layer 124.

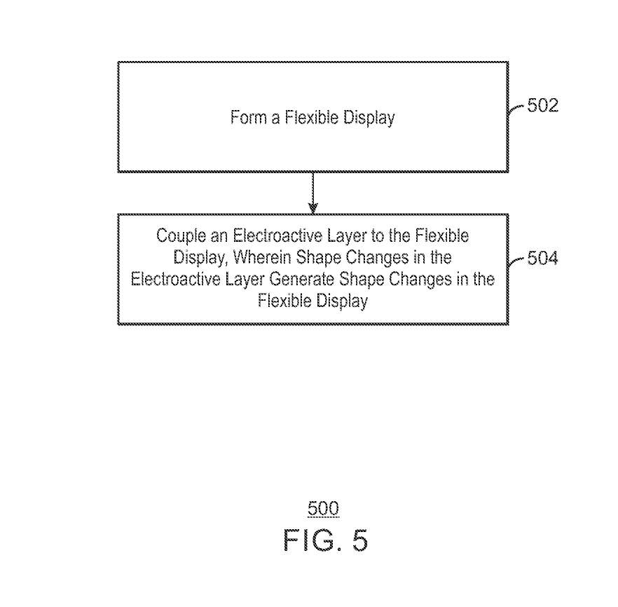

FIG. 5 is a block diagram illustrating a method for forming a shape changing flexible display. The method 500 includes, at block 502, forming a flexible display. At block 504, the method may include coupling an electroactive layer to the flexible display. The electromagnetic layer is coupled to the flexible display such that shape changes in the electromagnetic layer generate shape changes in the flexible display.

In some cases, method 500 may include coupling the electroactive layer to a controller to generate shape changes of the flexible display based on a condition. For example, the condition may include one or more user settings. In some cases, the condition may include user preferences associated with a given user profile. In some cases, the condition may include content of images displayed at the flexible display. In this case, the flexible display may change shape to enhance viewing. In some cases, the flexible display may change shape based on a detected viewing angle of a user in relationship to the flexible display. In some cases, the condition includes contextual data indicating an environment within which the flexible display is disposed. In some cases, the condition includes any combination of the conditions described herein. In any case, the flexible display has a shape that can be dynamically changed by the controller.

As discussed above, the electrostatic layer may include one or more characteristics enabling multiple curves to be displayed. In some cases, the method 500 may include coupling multiple sections of the electroactive material to different regions of the flexible display. In any case, the characteristics may enable the flexible display to be shaped into many and various different types of shapes.

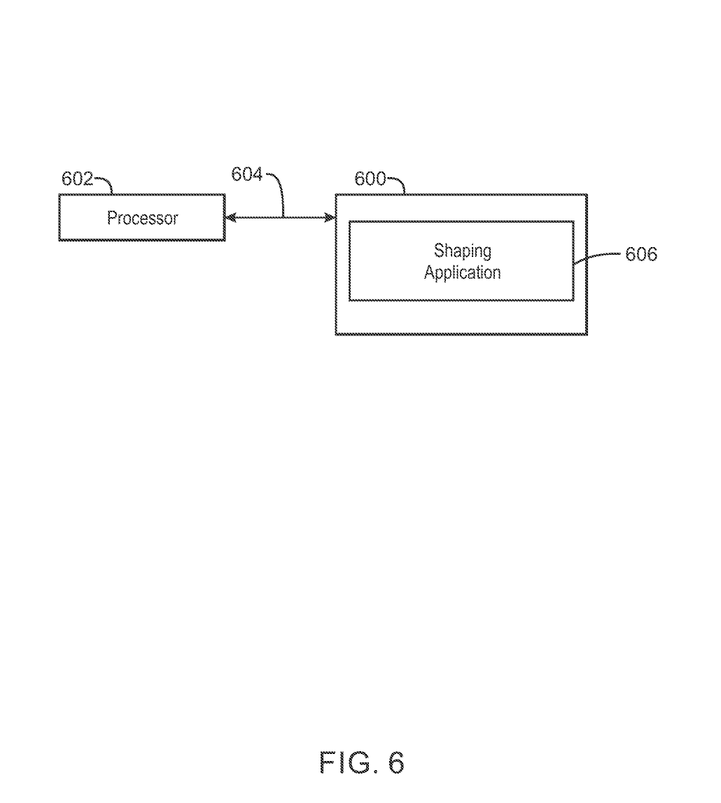

FIG. 6 is a block diagram depicting an example of a computer-readable medium configured to implement shape changes at a flexible display. The computer-readable medium 600 may be accessed by a processor 602 over a computer bus 604. In some examples, the computer-readable medium 600 may be a non-transitory computer-readable medium. In some examples, the computer-readable medium may be a storage medium. However, in any case, the computer-readable medium does not include transitory media such as carrier waves, signals, and the like. Furthermore, the computer-readable medium 600 may include computer-executable instructions to direct the processor 602 to perform the steps of the current method.

The various software components discussed herein may be stored on the tangible, non-transitory, computer-readable medium 600, as indicated in FIG. 6. For example, a shaping application 606 may be configured to generate shape changes of a flexible display, such as the flexible display 122 of FIG. 1.

Examples may include subject matter such as a method, means for performing acts of the method, at least one machine-readable medium including instructions that, when performed by a machine cause the machine to performs acts of the method. It is to be understood that specifics in the aforementioned examples may be used anywhere in one or more embodiments. For instance, all optional features of the computing device described above may also be implemented with respect to either of the methods described herein or a computer-readable medium. Furthermore, although flow diagrams and/or state diagrams may have been used herein to describe embodiments, the present techniques are not limited to those diagrams or to corresponding descriptions herein. For example, flow need not move through each illustrated box or state or in exactly the same order as illustrated and described herein.

Example 1 includes an apparatus. The apparatus includes a flexible display. The apparatus also includes an electroactive layer coupled to the flexible display. Shape changes in the electroactive layer generate shape changes in the flexible display.

Example 1 may include any combination of the cases discussed below. In some cases, the apparatus further includes a controller having logic, at least partially including hardware logic, to generate shape changes of the flexible display based on a condition. The condition may include one or more user settings, user preferences associated with a given user profile, content of images displayed at the flexible display, contextual data indicating an environment within which the flexible display is disposed, or any combination thereof.

In some cases, one or more characteristics of the electroactive layer are to generate a plurality of curves based on different levels of electric force. The one or more characteristics of the electroactive material may include a plurality of sections. At least two of the plurality of sections may be configured to receive electric force at different levels. A shape of the flexible display includes a plurality of curves is generated by receiving the different levels of electric force to at least two of the plurality of electroactive sections.

Example 2 includes a method. The method includes forming a flexible display, and coupling an electroactive layer to the flexible display, wherein shape changes in the electroactive layer generate shape changes in the flexible display.

Example 2 includes any combination of the cases discussed below. In some cases, the method includes coupling the electroactive layer to a controller to generate shape changes of the flexible display based on a condition. The condition may include one or more user settings, user preferences associated with a given user profile, content of images displayed at the flexible display, contextual data indicating an environment within which the flexible display is disposed, or any combination thereof.

In some cases, one or more characteristics of the electroactive layer are to generate a plurality of curves based on different levels of electric force. The one or more characteristics of the electroactive material may include a plurality of sections. At least two of the plurality of sections may be configured to receive electric force at different levels. A shape of the flexible display includes a plurality of curves is generated by receiving the different levels of electric force to at least two of the plurality of electroactive sections.

Example 3 includes a system. The system includes a flexible display, an electroactive layer coupled to the flexible display, wherein shape changes in the electroactive layer generate shape changes in the flexible display, and a controller having logic, at least partially comprising hardware logic, to generate shape changes of the flexible display.

Example 3 includes any combination of the cases discussed below. In some cases, the logic is to be carried out by a processing device. The condition may include one or more user settings, user preferences associated with a given user profile, content of images displayed at the flexible display, contextual data indicating an environment within which the flexible display is disposed, or any combination thereof.

In some cases, one or more characteristics of the electroactive layer are to generate a plurality of curves based on different levels of electric force. The one or more characteristics of the electroactive material may include a plurality of sections. At least two of the plurality of sections may be configured to receive electric force at different levels. A shape of the flexible display includes a plurality of curves is generated by receiving the different levels of electric force to at least two of the plurality of electroactive sections.

Example 4 includes an apparatus. The apparatus includes a flexible display. The apparatus also includes an electroactive layer coupled to the flexible display. Shape changes in the electroactive layer generate shape changes in the flexible display.

Example 4 may include any combination of the cases discussed below. In some cases, the apparatus further includes a means for generating shape changes of the flexible display based on a condition. The condition may include one or more user settings, user preferences associated with a given user profile, content of images displayed at the flexible display, contextual data indicating an environment within which the flexible display is disposed, or any combination thereof.

In some cases, one or more characteristics of the electroactive layer are to generate a plurality of curves based on different levels of electric force. The one or more characteristics of the electroactive material may include a plurality of sections. At least two of the plurality of sections may be configured to receive electric force at different levels. A shape of the flexible display includes a plurality of curves is generated by receiving the different levels of electric force to at least two of the plurality of electroactive sections.

Example 5 includes a method. The method includes forming a flexible display, and coupling an electroactive layer to the flexible display, wherein shape changes in the electroactive layer generate shape changes in the flexible display.

Example 5 includes any combination of the cases discussed below. In some cases, the method includes coupling the electroactive layer to a means for generating shape changes of the flexible display based on a condition. The condition may include one or more user settings, user preferences associated with a given user profile, content of images displayed at the flexible display, contextual data indicating an environment within which the flexible display is disposed, or any combination thereof.

In some cases, one or more characteristics of the electroactive layer are to generate a plurality of curves based on different levels of electric force. The one or more characteristics of the electroactive material may include a plurality of sections. At least two of the plurality of sections may be configured to receive electric force at different levels. A shape of the flexible display includes a plurality of curves is generated by receiving the different levels of electric force to at least two of the plurality of electroactive sections.

In the above description and the following claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine, e.g., a computer. For example, a machine-readable medium may include read only memory (ROM); random access memory (RAM); magnetic disk storage media; optical storage media; flash memory devices.

An embodiment is an implementation or example. Reference in the present specification to “an embodiment”, “one embodiment”, “some embodiments”, “various embodiments”, or “other embodiments” means that a particular feature, structure, or characteristic described in connection with the embodiments is included in at least some embodiments, but not necessarily all embodiments, of the present techniques. The various appearances of “an embodiment”, “one embodiment”, or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. An apparatus, comprising:
a flexible display; and
an electroactive layer coupled to the flexible display, wherein shape changes in the electroactive layer generate shape changes in the flexible display.

2. The apparatus of claim 1, further comprising a controller having logic, at least partially comprising hardware logic, to generate shape changes of the flexible display based on a condition.

3. The apparatus of claim 2, wherein the condition comprises one or more user settings.

4. The apparatus of claim 2, wherein the user settings comprise user preferences associated with a given user profile.

5. The apparatus of claim 2, wherein the condition comprises content of images displayed at the flexible display.

6. The apparatus of claim 2, wherein the condition comprises contextual data indicating an environment within which the flexible display is disposed.

7. The apparatus of claim 1, wherein one or more characteristics of the electroactive layer are to generate a plurality of curves based on different levels of electric force.

8. The apparatus of claim 7, wherein the one or more characteristics of the electroactive material comprise a plurality of sections.

9. The apparatus of claim 8, wherein at least two of the plurality of sections are configured to receive electric force at different levels.

10. The apparatus of claim 9, wherein a shape of the flexible display comprises a plurality of curves is generated by receiving the different levels of electric force to at least two of the plurality of electroactive sections.

11. A method, comprising:
forming a flexible display; and
coupling an electroactive layer to the flexible display, wherein shape changes in the electroactive layer generate shape changes in the flexible display.

12. The method of claim 11, further comprising coupling the electroactive layer to a controller to generate shape changes of the flexible display based on a condition.

13. The method of claim 12, wherein the condition comprises one or more user settings.

14. The method of claim 12, wherein the user settings comprise user preferences associated with a given user profile.

15. The method of claim 12, wherein the condition comprises content of images displayed at the flexible display.

16. The method of claim 12, wherein the condition comprises contextual data indicating an environment within which the flexible display is disposed.

17. The method of claim 11, wherein one or more characteristics of the electroactive layer are to generate a plurality of curves based on different levels of electric force.

18. The method of claim 17, wherein the one or more characteristics of the electroactive material comprise a plurality of sections.

19. The method of claim 18, wherein at least two of the plurality of sections are configured to receive electric force at different levels.

20. The method of claim 19, wherein a shape of the flexible display comprises a plurality of curves generated by receiving the different levels of electric force to at least two of the plurality of electroactive sections.

21. A system, comprising:
a flexible display;
an electroactive layer coupled to the flexible display, wherein shape changes in the electroactive layer generate shape changes in the flexible display; and
a controller having logic, at least partially comprising hardware logic, to generate shape changes of the flexible display.

22. The system of claim 21, wherein the shape changes are based one or more conditions, the one or more conditions comprising:
one or more user settings;
one or more user preferences associated with a given user profile;
content of images displayed at the flexible display;
contextual data indicating an environment within which the flexible display is disposed; or
any combination thereof.

23. The system of claim 21, wherein the electroactive layer comprises one or more characteristics configured to generate a plurality of curves based on different levels of electric force.

24. The system of claim 23, wherein the one or more characteristics of the electroactive material comprise a plurality of sections.

25. The system of claim 24, wherein at least two of the plurality of sections are configured to receive electric force at different levels.
